(19) United States
(12) Patent Application Publication
(10) Pub. No.: US 2011/0207306 A1
(43) Pub. Date: Aug. 25, 2011

(54) SEMICONDUCTOR STRUCTURE MADE USING IMPROVED ION IMPLANTATION PROCESS

(76) Inventors: Sarko Cherekdjian, Campbell, CA (US); Yuko Fujimoto, Minakuchi-cho (JP); Richard Orr Maschmeyer, Corning, NY (US); Takeshi Matsumoto, Minakuchi-cho (JP)

(21) Appl. No.: 12/709,833

(22) Filed: Feb. 22, 2010

(51) Int. Cl. H01L 21/265

(52) U.S. Cl. 438/513; 257/E21.334

(57) ABSTRACT

Methods and apparatus for producing a semiconductor structure include: subjecting an implantation surface of a semiconductor wafer to an ion implantation process to create an exfoliation layer therein, wherein the ion implantation process includes simultaneously implanting two different species of ions into the implantation surface of the semiconductor wafer.

### BACKGROUND

The features, aspects and embodiments disclosed herein relate to the manufacture of semiconductor devices, such as semiconductor-on-insulator (SOI) structures, using an improved ion implantation process.

To date, the semiconductor material most commonly used in semiconductor-on-insulator structures has been silicon. Such structures have been referred to in the literature as silicon-on-insulator structures and the abbreviation “SOI” has been applied to such structures. SOI technology is becoming increasingly important for high performance thin film transistors, solar cells, and displays, such as active matrix displays. SOI structures may include a thin layer of substantially single crystal silicon on an insulating material.

Various ways of obtaining SOI structures include epitaxial growth of silicon (Si) on lattice matched substrates. An alternative process includes the bonding of a single crystal silicon wafer to another silicon wafer on which an oxide layer of SiO₂ has been grown, followed by polishing or etching of the top wafer down to, for example, a 0.05 to 0.3 micron layer of single crystal silicon. Further methods include ion-implantation methods in which either hydrogen or oxygen ions are implanted either to form a buried oxide layer in the silicon wafer topped by Si in the case of oxygen ion implantation or to separate (exfoliate) a thin Si layer to bond to another Si wafer with an oxide layer as in the case of hydrogen ion implantation.

Manufacture of SOI structures by these methods is costly. The latter method involving hydrogen ion implantation has received some attention and has been considered advantageous over the former methods because the implantation energies required are less than 50% of that of oxygen ion implants and the dosage required is two orders of magnitude lower.

U.S. Pat. No. 7,176,528 discloses a process that produces silicon on glass (SiOG) structure. The steps include: (i) exposing a silicon wafer surface to hydrogen ion implantation to create a bonding surface; (ii) bringing the bonding surface of the wafer into contact with a glass substrate; (iii) applying pressure, temperature and voltage to the wafer and the glass substrate to facilitate bonding therebetween; (iv) cooling the structure to a common temperature; and (v) separating the glass substrate and a thin layer of silicon from the silicon wafer.

Although the manufacturing processes for making SOI structures is maturing, the commercial viability and/or application of final products employing them is limited by cost concerns. A significant cost in producing an SOI structure using the process disclosed in U.S. Pat. No. 7,176,528 is incurred during the ion implantation step. It is believed that reductions in the cost of carrying out the ion implantation process would improve the commercial application of SOI structures. Accordingly, it is desirable to continue to advance the efficiency of producing SOI structures.

### SUMMARY

Although the features, aspects and embodiments disclosed herein may be discussed in relation to the manufacture of semiconductor-on-insulator (SOI) structures, skilled artisans will understand that such disclosure need not be limited to SOI manufacturing. Indeed, the broadest protectable features, aspects, etc. disclosed herein are applicable to any process in which ion implantation into (or onto) semiconductor material is required, whether such semiconductor material is used in conjunction with an insulator or otherwise.

For ease of presentation, however, the disclosure herein may be made in relation to the manufacture of SOI structures. The specific references made herein to SOI structures are to facilitate the explanation of the disclosed embodiments and are not intended to, and should not be interpreted as, limiting the scope of the claims in any way. The SOI abbreviation is used herein to refer to semiconductor-on-insulator structures in general, including, but not limited to, semiconductor-on-glass (SOG) structures, silicon-on-insulator (SOI) structures, and silicon-on-glass (SiOG) structures, which also encompasses silicon-on-glass-ceramic structures. In the context of this description, SOI may also refer to semiconductor-on-semiconductor structures, such as silicon-on-silicon structures, etc.

In accordance with one or more embodiments herein, methods and apparatus of forming a semiconductor structure, include: subjecting an implantation surface of a semiconductor wafer to an ion implantation process to create an exfoliation layer therein, wherein the ion implantation process includes simultaneously implanting two different species of ions into the implantation surface of the semiconductor wafer.

The two different species of ions may be taken from the group consisting of: boron, hydrogen, and helium, or any other suitable element.

Heat treating the semiconductor wafer may be carried out such that, in the case of H and He implantation, the He ions migrate towards the area of weakening created by the H ions below the implantation surface of the semiconductor wafer.

Other aspects, features, advantages, etc. will become apparent to one skilled in the art when the description of the embodiments herein is taken in conjunction with the accompanying drawings.

### BRIEF DESCRIPTION OF THE DRAWINGS

For the purposes of illustrating the various aspects and features disclosed herein, there are shown in the drawings forms that are presently preferred, it being understood, however, that the covered embodiments are not limited to the precise arrangements and instrumentalities shown.

FIG. 1 is a block diagram illustrating the structure of a semiconductor device in accordance with one or more embodiments disclosed herein;

FIGS. 2-5 are schematic diagrams illustrating intermediate structures formed using processes of manufacturing the semiconductor device of FIG. 1;

FIG. 6 is a simplified block diagram and schematic diagram of an apparatus (an ion shower implant tool) suitable for implanting a donor semiconductor wafer with ions to produce an intermediate structure useful in manufacturing the semiconductor device of FIG. 1;

FIG. 7 is a simplified block diagram and schematic diagram of an alternative apparatus (ion immersion implant tool) suitable for implanting a donor semiconductor wafer with ions to produce an intermediate structure useful in manufacturing the semiconductor device of FIG. 1; and

FIGS. 8A-8B are graphical illustrations of the TOF-SIMS analysis of a semiconductor wafer implanted using the apparatus of FIG. 6.

### DETAILED DESCRIPTION

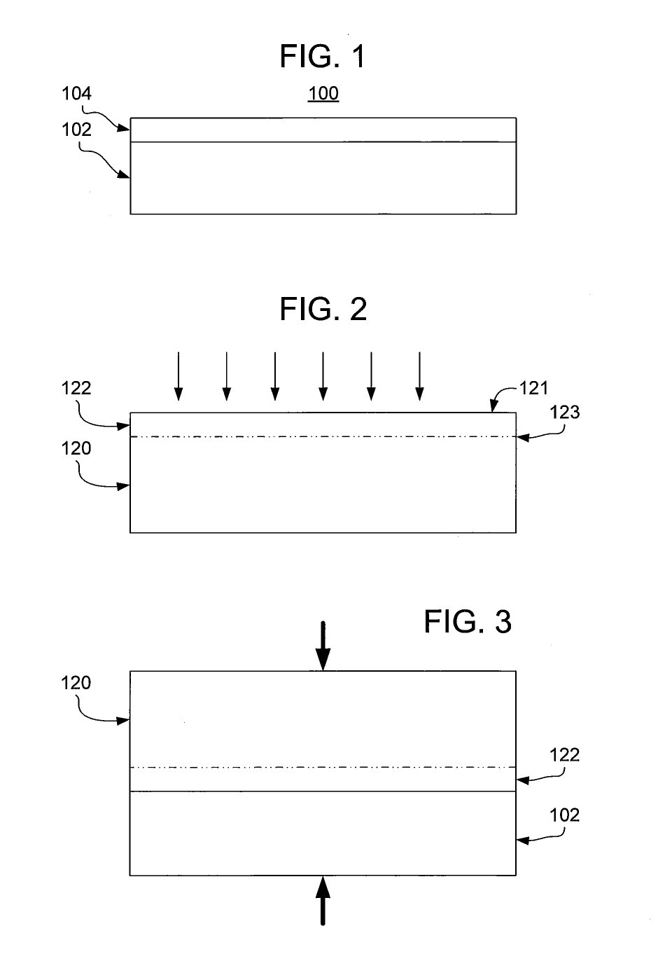

With reference to the drawings, wherein like numerals indicate like elements, there is shown in FIG. 1 a semiconductor-on-substrate structure 100 in accordance with one or more embodiments disclosed herein. In order to provide some specific context in which to discuss the broadest protectable features and aspects disclosed herein, it will be assumed that the semiconductor-on-substrate structure 100 is an SOI structure, such as a semiconductor-on-glass structure.

The SOI structure 100 may include a substrate 102, and a semiconductor layer 104. Such an SOI structure 100 may have suitable uses in connection with fabricating thin film transistors (TFTs), e.g., for display applications, including organic light-emitting diode (OLED) displays and liquid crystal displays (LCDs), integrated circuits, photovoltaic devices, etc. Although not required, the semiconductor material of the layer 104 may be in the form of a substantially single-crystal material. The word “substantially” is used in describing the layer 104 to take into account the fact that semiconductor materials normally contain at least some internal or surface defects either inherently or purposely added, such as lattice defects or a few grain boundaries. The word “substantially” also reflects the fact that certain dopants may distort or otherwise affect the crystal structure of the bulk semiconductor.

For the purposes of discussion, it is assumed that the semiconductor layer 104 is formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, and InP.

The substrate 102, may be any desirable material exhibiting any desirable characteristics. For example, in some embodiments, the substrate 102 may be formed from a semiconductor material, such as the above-listed varieties.

In accordance with alternative embodiments, the substrate 102 may be an insulator, such as glass, an oxide glass, or an oxide glass-ceramic. As between oxide glasses and oxide glass-ceramics, the glass may have the advantage of being simpler to manufacture, thus making them more widely available and less expensive. By way of example, a glass substrate 102 may be formed from glass containing alkaline-earth ions, such as, substrates made of CORNING INCORPORATED GLASS COMPOSITION NO. 1737 or CORNING INCORPORATED GLASS COMPOSITION NO. EAGLE 2000™. These glass materials have particular use in, for example, the production of liquid crystal displays.

While the subject matter of particular interest herein involves ion implantation into semiconductor material, it is believed that providing some additional context in terms of a specific process for manufacturing the SOI 100 is beneficial. Thus, reference is now made to FIGS. 2-5, which illustrate a general process (and resultant intermediate structures) within which the aforementioned ion implantation may be carried out in order to manufacture the SOI structure 100 of FIG. 1.

Turning first to FIG. 2, a donor semiconductor wafer 120 is prepared, such as by polishing, cleaning, etc. to produce a relatively flat and uniform implantation surface 121 suitable for bonding to the substrate 102, e.g., a glass or glass-ceramic substrate. For the purposes of discussion, the semiconductor wafer 120 may be a substantially single crystal Si wafer, although as discussed above any other suitable semiconductor conductor material may be employed.

An exfoliation layer 122 is created by subjecting the implantation surface 121 to an ion implantation process to create a weakened region 123 below the implantation surface 121 of the donor semiconductor wafer 120. Although it is this ion implantation process that is the focus of the disclosure herein, at this point only general reference will be made to the process for creating the weakened region 123. Later in this description, however, a more detailed discussion of one or more ion implantation processes of specific interest will be provided. The ion implantation energy may be adjusted using to achieve a general thickness of the exfoliation layer 122, such as between about 300-500 nm, although any reasonable thickness may be achieved. The effect of ion implantation into the donor semiconductor wafer 120 is the displacement of atoms in the crystal lattice from their regular locations. When the atom in the lattice is hit by an ion, the atom is forced out of position and a primary defect, a vacancy and an interstitial atom, is created, which is called a Frenkel pair. If the implantation is performed near room temperature, the components of the primary defect move and create many types of secondary defects, such as vacancy clusters, etc.

With reference to FIG. 3, the substrate 102 may be bonded to the exfoliation layer 122 using an electrolysis process (also referred to herein as an anodic bonding process). A basis for a suitable electrolysis bonding process may be found in U.S. Pat. No. 7,176,528, the entire disclosure of which is hereby incorporated by reference. Portions of this process are discussed below; however, one or more embodiments described herein are directed to modifications of the ion implantation process of U.S. Pat. No. 7,176,528.

In the bonding process, appropriate surface cleaning of the substrate 102 (and the exfoliation layer 122 if not done already) may be carried out. Thereafter, the intermediate structures are brought into direct or indirect contact. The resulting intermediate structure is thus a stack, including the bulk material layer of the donor semiconductor wafer 120, the exfoliation layer 122, and the glass substrate 102.

Prior to or after the contact, the stack of the donor semiconductor wafer 120, the exfoliation layer 122, and the glass substrate 102 is heated (indicated by the arrows in FIG. 3). The glass substrate 102 and the donor semiconductor wafer 120 are taken to a temperature sufficient to induce ion migration within the stack and an anodic bond therebetween. The temperature is dependent on the semiconductor material of the donor wafer 120 and the characteristics of the glass substrate 102. By way of example, the temperature of the junction may be taken to within about +/−350° C. of a strain point of the glass substrate 102, more particularly between about −250° C. and 0° C. of the strain point, and/or between about −100° C. and −50° C. of the strain point. Depending on the type of glass, such temperature may be in the range of about 500-600° C.

In addition to the above-discussed temperature characteristics, mechanical pressure (indicated by the arrows in FIG. 3) is applied to the intermediate assembly. The pressure range may be between about 1 to about 50 psi. Application of higher pressures, e.g., pressures above 100 psi, might cause breakage of the glass substrate 102.

A voltage (indicated by the arrows in FIG. 3) is also applied across the intermediate assembly, for example with the donor semiconductor wafer 120 at the positive electrode and the glass substrate 102 the negative electrode. The application of the voltage potential causes alkali or alkaline earth ions in the glass substrate 102 to move away from the semiconductor/glass interface further into the glass substrate 102. More particularly, positive ions of the glass substrate 102, including substantially all modifier positive ions, migrate away from the higher voltage potential of the donor semiconductor wafer 120, forming: (1) a reduced positive ion concentration layer in the glass substrate 102 adjacent the exfoliation layer 122; and (2) an enhanced positive ion concentration layer of the glass substrate 102 adjacent the reduced positive ion concentration layer. This formation results in barrier functionality, i.e., preventing positive ion migration back from the oxide glass or oxide glass-ceramic, through the reduced positive ion concentration layer, and into the semiconductor layer.

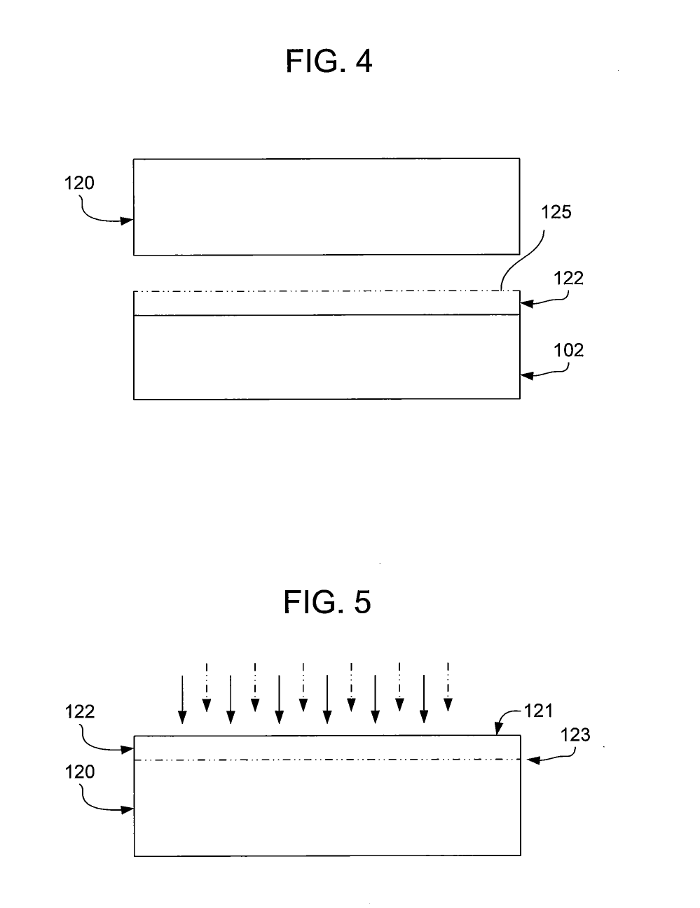

With reference to FIG. 4, after the intermediate assembly is held under the conditions of temperature, pressure and voltage for a sufficient time, the voltage is removed and the intermediate assembly is allowed to cool to room temperature. At some point during heating, during a dwell, during cooling, and/or after cooling, the donor semiconductor wafer 120 and the glass substrate 102 are separated. This may include some peeling if the exfoliation layer 122 has not already become completely free from the donor 120. The result is a glass substrate 102 with the relatively thin exfoliation layer 122 formed of the semiconductor material of the donor semiconductor layer 120 bonded thereto. The separation may be accomplished via fracture of the exfoliation layer 122 due to thermal stresses. Alternatively or in addition, mechanical stresses such as water jet cutting or chemical etching may be used to facilitate the separation.

The cleaved surface 125 of the SOI structure 100, just after exfoliation, may exhibit surface roughness, excessive silicon layer thickness, and/or implantation damage of the silicon layer (e.g., due to the formation of an amorphized silicon layer). Depending on the implantation energy and implantation time, the thickness of the exfoliation layer 122 may be on the order of about 300-500 nm, although other thicknesses may also be suitable. These characteristics may be altered using post bonding processes in order to advance from the exfoliation layer 122 and produce the desirable characteristics of the semiconductor layer 104 (FIG. 1). It is noted that the donor semiconductor wafer 120 may be reused to continue producing other SOI structures 100.

Reference is now made to FIG. 5, which is again directed to the creation of the exfoliation layer 122 by subjecting the implantation surface 121 of the donor semiconductor wafer 120 to an ion implantation process to create the weakened region 123 below the implantation surface 121 of the donor semiconductor wafer 120. In accordance with one or more embodiments, the ion implantation process includes simultaneously implanting two different species of ions into the implantation surface 121 of the donor semiconductor wafer 120.

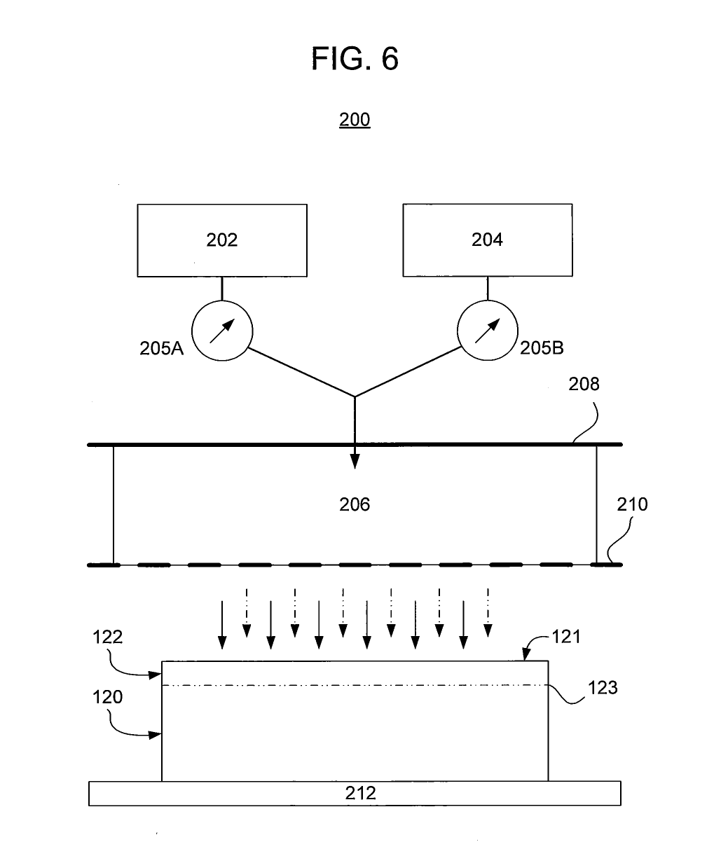

With reference to FIG. 6, the simultaneous implantation of the two different types of ions may be carried out in an ion shower implant tool 200. Such an ion shower tool 200 may be purchased commercially and then modified to achieve the process described herein. As the design and operating principle of implant tools may differ, the specific modifications in equipment and/or operation will be left to the skilled artisan.

The ion shower tool 200 of FIG. 6 is illustrated in high-level schematic form. The tool 200 includes: first and second sources of gas, e.g. a first tank 202 and a second tank 204, a plasma chamber 206, a first electrode 208, a second electrode (grid) 210, and a transport mechanism 212. Each of the sources of gas 202, 204 is intended to illustrate that different types of gas are introduced into the plasma chamber 206, namely a first type of gas and at least a second type of gas. The different species of gas may be taken from the group consisting of boron, hydrogen, and helium, or any other suitable element or gas. For example, the first gas may be hydrogen and the second gas may be helium. Instead of two separate tanks of gas as illustrated, a single tank containing a mixture of both of the desired gasses, such as hydrogen and helium, at desired ratio of one gas to the other may be employed as the source of gas for feeding the plasma chamber 206.

Conditions are established within the plasma chamber 206 to ensure that desirable ion acceleration and energy levels are achieved to produce plasma of each gas. For example, a gas within the chamber 206 is excited to form plasma, which may be achieved via an RF antenna (not shown). The positively charged first and second gas ions are accelerated towards the donor semiconductor wafer 120 by way of an electric field between the first and second electrodes 208, 210. (It is noted that in a practical piece of equipment, there may be one or more additional electrodes, not shown, which contribute to and/or produce the required plasma and acceleration.) The field may be of sufficient magnitude to accelerate the first and second ions to an energy of between about 25-150 KeV, such as about 80 KeV. As the second electrode 210 is in the form of a grid, the ions may pass therethrough and strike the implantation surface 121 of the donor semiconductor wafer 120 and become implanted in the donor semiconductor. The energy to which the first and second ions are accelerated is selected such that the ions are implanted in the donor semiconductor wafer to the desired depth, e.g. approximately along the desired weakened region 123 below the implantation surface 121 of the donor semiconductor wafer 120. Mass flow control valves or needle valves 205A, 205B may be located in the gas feed lines between the first and second tanks 202, 204 in order to control the ratio of the first gas to the second gas in the plasma chamber 206 and thereby control the ratio of first ions to second ions implanted into the semiconductor donor wafer 120. The ratio of the first ions to the second ions being implanted may also be controlled by adjusting the distribution of the plasma in the plasma chamber 206 by controlling one or more of the arc voltage, arc current, and the biasing platen.

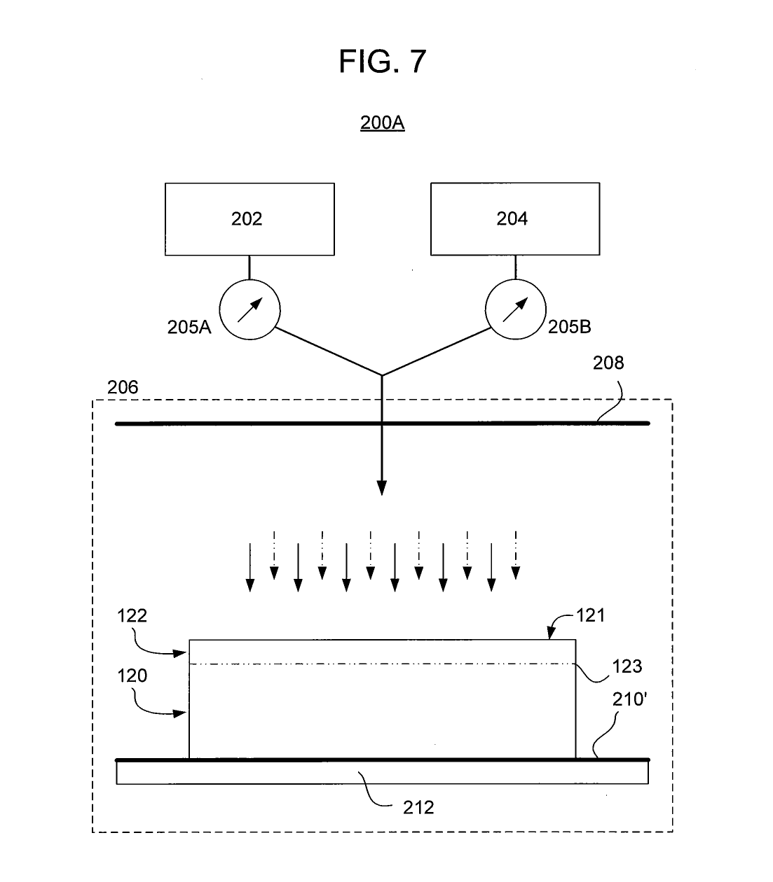

The specific type of implantation technique carried out within the ion implant tool 200 is not limited to ion shower type implant tools. Other suitable ion implantation techniques include plasma immersion ion implantation techniques. With reference to FIG. 7, in a plasma immersion implant tool 200A, the donor semiconductor wafer 120 is placed in the plasma chamber 206 and forms the second electrode 210′. The positively charged gas ions are accelerated towards the donor semiconductor wafer 120 by way of an electric field created between the first electrode 208 and the second electrode 210′ (i.e., the donor semiconductor wafer 120.

### Example

A donor silicon wafer of was implanted with both hydrogen and helium ions at an implantation energy of 80 KeV, a scan speed of 100 mm/s, an ion beam current density of 500 uA/cm, and gas flow ratios of hydrogen to helium of 8/32 ccm. The ion beam current was measured prior to implantation and efforts were made to ensure that the beam current was uniform. It is contemplated to outfit the tool 200 with a beam current detector and mass separation function in order to provide monitoring of, and control over, the hydrogen/helium ion ratio. The transport mechanism 212 of the tool 200 was used to scan the donor silicon wafer 120 back and forth a suitable number of times in order to achieve a target dose.

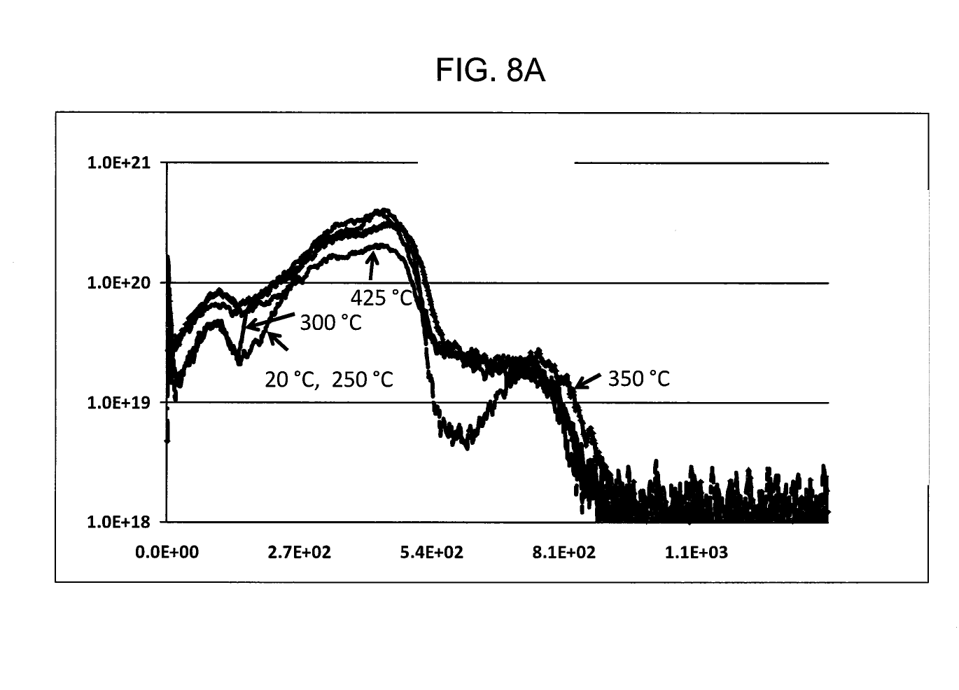

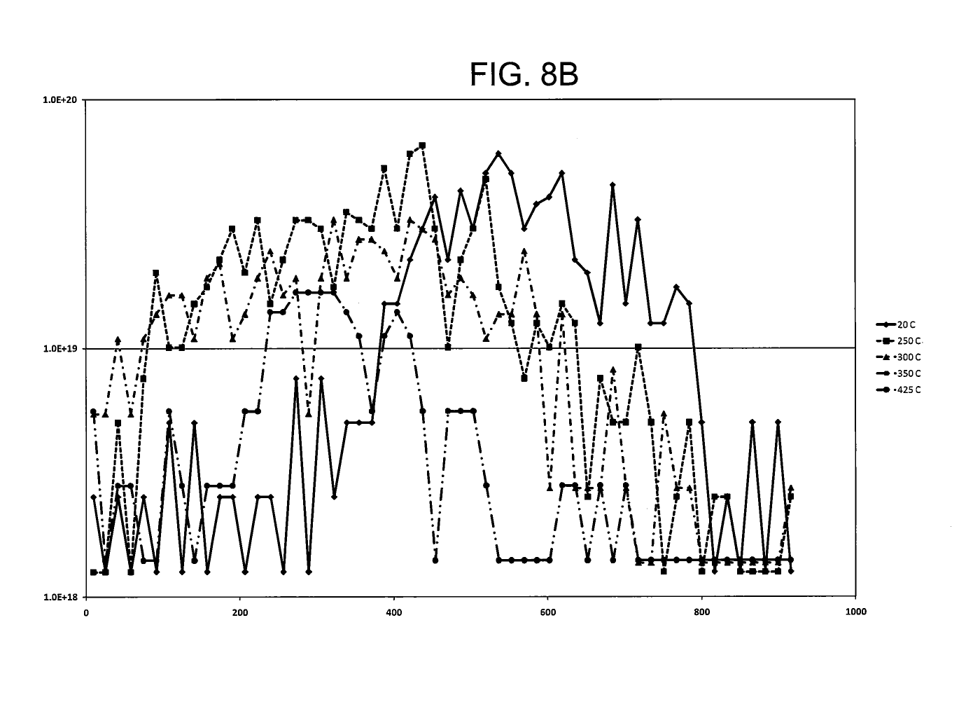

After the simultaneous implantation of hydrogen and helium ions into the donor silicon wafer 120, the sample was separated into five pieces. Each sample was heat treated for about four hours at different temperatures: 20° C., 250° C., 300° C., 350° C., and 425° C. The samples were then measured for hydrogen and helium depth profile via TOF-SIMS analysis. The results of the TOF-SIMS analysis are shown in FIGS. 8A-8B, where FIG. 8A is the plot of hydrogen depth and FIG. 8B is the plot of helium depth. In each chart, the Y-axis shows the ion concentration in atoms/cm2, and the X-axis shown implant depth in nano-meters.

It is noted that the peak concentration of hydrogen occurs at a depth that remains substantially stable at about 400 nm. The room temperature (20° C.) peak concentration of helium, however, lies at a depth of about 600 nm. With heat treatment, the peak concentration of helium migrates to about 400 nm.

Although the aspects, features, and embodiments disclosed herein have been described with reference to particular details, it is to be understood that these details are merely illustrative of broader principles and applications. It is therefore to be understood that numerous modifications may be made to the illustrative embodiments and that other arrangements may be devised without departing from the spirit and scope of the appended claims.

1. A method of forming a semiconductor structure, comprising:
subjecting a surface of a semiconductor wafer to an ion shower process to create an exfoliation layer therein,
wherein the ion shower process includes simultaneously showering two different species of ions onto the surface of the semiconductor wafer.

2. The method of claim 1, wherein the step of simultaneously showering two different species of ions includes simultaneously accelerating the two different species of ions towards the surface of the semiconductor wafer.

3. The method of claim 1, wherein the two different species of ions are taken from the group consisting of: boron, hydrogen, and helium.

4. The method of claim 1, further comprising controlling a ratio of the two different species of ions implanted into the semiconductor wafer.

5. The method of claim 1, further comprising heat treating the semiconductor wafer such that at least one of the two species of ions migrates towards the other to form an area of weakening below the surface of the semiconductor wafer.

6. The method of claim 1, wherein the ion shower is conducted at an energy of between about 25-150 KeV.

7. The method of claim 6, wherein the ion shower is conducted at an energy of about 80 KeV.

8. The method of claim 1, wherein the semiconductor wafer is taken from the group consisting of: silicon (Si), germanium-doped silicon (SiGe), silicon carbide (SiC), germanium (Ge), gallium arsenide (GaAs), GaP, and InP.

9. The method of claim 1, wherein the ion shower process comprises:
feeding a first type of gas and a second type of gas into a plasma chamber;
simultaneously exciting the first and second gas to form plasma in the plasma chamber, including a first species of ions of the first gas and second species of ions of the second gas; and
simultaneously accelerating the first species of ions and the second species of ions toward the surface of the semiconductor wafer, thereby showering in the first species of ions and the second species of ions onto the semiconductor wafer.

10. The method of claim 9, wherein the first and second species of ions are accelerated to an energy such that the first and second species of ions reach a depth below the surface of the semiconductor wafer that is near to a desired area of weakness below the surface of the semiconductor wafer.

11. The method of claim 9, wherein the first gas is hydrogen, the first species of ions is hydrogen, the second gas is helium, and the second species of ions is helium.

12. The method of claim 11, wherein the hydrogen gas and the helium gas are fed into the chamber at a gas flow ratio of hydrogen to helium of about 8/32.

13. The method of claim 12, wherein the hydrogen and the helium ions are simultaneously showered at an implantation energy of 80 KeV.

14. The method of claim 11, wherein
the hydrogen ions initially reach a first depth and the helium ions initially reach a second depth; and
the method further comprises heating the semiconductor wafer to cause the helium ions to migrate toward the hydrogen ions to form the desired are of weakness below the surface of the semiconductor wafer.

15. The method of claim 1, wherein the two different species of ions comprise hydrogen ions and helium ions.

16. The method of claim 12, wherein
the hydrogen ions initially reach a first depth and the helium ions initially reach a second depth; and
the method further comprises heating the semiconductor wafer to cause the helium ions to migrate toward the hydrogen ions.
